(19) United States
(12) Patent Application Publication
(10) Pub. No.: US 2004/0079974 A1
(43) Pub. Date: Apr. 29, 2004

(54) Method for manufacturing a semiconductor device using dummy openings in a photoresist material and an LDMOS device manufactured in accordance with the method

(75) Inventors: John Lin, Chelmsford, MA (US); Phil Hower, Concord, MA (US); Vladimir Bolkhovsky, Framingham, MA (US); Binghua Hu, Plano, TX (US)

Correspondence Address: TEXAS INSTRUMENTS INCORPORATED, P O BOX 655474, M/S 3999, DALLAS, TX, 75265

(73) Assignee: Texas Instruments Incorporated, Dallas, TX

(21) Appl. No.: 10/279,316

(22) Filed: Oct. 24, 2002

(51) Int. Cl. H01L 21/336; H01L 21/8234; H01L 29/76; H01L 31/062; H01L 31/119

(52) U.S. Cl. 257/288; 438/197; 438/276

(57) ABSTRACT

The present invention provides a method for manufacturing a semiconductor device, an associated method for manufacturing an integrated circuit, and an LDMOS device manufactured in accordance with the method for manufacturing the semiconductor device. The method for manufacturing the semiconductor device, in one embodiment, may include depositing a layer of photoresist material over a substrate and creating an active device opening having sidewall angles associated therewith through the photoresist material. Additionally, the method may include forming a dummy opening through the photoresist material, wherein the dummy opening is located proximate the active device opening to reduce a shrinkage of the photoresist between the dummy opening and the active device opening and thereby inhibit nonuniform distortion of the sidewall angles.

### TECHNICAL FIELD OF THE INVENTION

The present invention is directed, in general, to a method for manufacturing a semiconductor device and, more specifically, to a method for manufacturing a semiconductor device using dummy openings in a photoresist material, an associated method for manufacturing an integrated circuit, and an LDMOS device manufacturing according to the method.

### BACKGROUND OF THE INVENTION

Laterally diffused metal oxide semiconductor (LDMOS) devices are commonly used and well known in the microelectronics industry. Such LDMOS devices are generally used in an area of microelectronics called power management. Power management refers to a collection of circuits used to control the delivery of power to a particular device, such as a microprocessor, optical device, micro-electro-mechanical system (MEMS) device or another device.

Most recently, LDMOS devices have undergone a number of manufacturing and structural changes, each of which make attaining certain desired operating characteristics increasingly difficult. One specific operating characteristic that has become increasingly difficult for the most recent LDMOS devices to achieve is a relatively low threshold voltage (Vₜ). A number of present day LDMOS devices require threshold voltages (Vₜ) approaching 2.0 volts or less, which is a number that is becoming harder and harder to achieve.

It has been determined that one element hampering the most recent LDMOS devices' ability to achieve the aforementioned low threshold voltage (Vₜ), is the inability of the industry to achieve steep sidewall angles in the photoresist that is used to define the LDMOS well that determines this threshold voltage (Vₜ). Turning to Prior Art FIG. 1, illustrated is a graph 100 depicting the effect that various sidewall angles have on achieving a desired threshold voltage (Vₜ) for older LDMOS devices 110 versus the most recent LDMOS devices 120. As depicted in FIG. 1, where the older devices 110 are capable of obtaining threshold voltage (Vₜ) values of less than about 2.0 volts using sidewall angles of 60 degrees or greater, current LDMOS devices 120 require sidewall angles of greater than about 86 degrees to achieve the same threshold voltage (Vₜ) values.

Herein arises the problem. Namely, the photoresist materials and thicknesses currently used are generally not capable of consistently providing the steep sidewall angles required to attain the threshold voltage (Vₜ) values desired. While the industry has made several attempts directed to correcting the sidewall angle problem, none of the attempts have proven consistently successful to the degree required by manufacturing quality standards.

Accordingly, what is needed in the art is a method for manufacturing a semiconductor device that does not experience the photoresist sidewall issues experienced by the prior art devices.

### SUMMARY OF THE INVENTION

To address the above-discussed deficiencies of the prior art, the present invention provides a method for manufacturing a semiconductor device, an associated method for manufacturing an integrated circuit, and an LDMOS device manufactured in accordance with the method for manufacturing the semiconductor device. The method for manufacturing the semiconductor device, in one embodiment, includes depositing a layer of photoresist material over a substrate and creating an active device opening having sidewall angles associated therewith through the photoresist material. Additionally, the method includes forming a dummy opening through the photoresist material, wherein the dummy opening is located proximate the active device opening to reduce a shrinkage of the photoresist between the dummy opening and the active device opening, and thereby inhibit nonuniform distortion of the sidewall angles.

As mentioned above, the present invention further includes an LDMOS device constructed in accordance with the method described. The LDMOS device may include a gate located over an LDMOS well doped with a dopant, wherein the LDMOS well is located in a deep well doped with an opposite dopant. Further, the LDMOS device may include a dummy LDMOS well located in a non-active device region and proximate the LDMOS well, wherein the dummy LDMOS well is doped with the opposite dopant.

The foregoing has outlined preferred and alternative features of the present invention so that those skilled in the art may better understand the detailed description of the invention that follows. Additional features of the invention will be described hereinafter that form the subject of the claims of the invention. Those skilled in the art should appreciate that they can readily use the disclosed conception and specific embodiment as a basis for designing or modifying other structures for carrying out the same purposes of the present invention. Those skilled in the art should also realize that such equivalent constructions do not depart from the spirit and scope of the invention.

### BRIEF DESCRIPTION OF THE DRAWINGS

For a more complete understanding of the present invention, reference is now made to the following descriptions taken in conjunction with the accompanying drawings, in which: Greg, should we use the longer introduction that we typically use?

Prior Art FIG. 1 illustrates a graph depicting the effect various sidewall angles have on achieving a desired threshold voltage (Vₜ) for older LDMOS devices versus the most recent LDMOS devices;

FIGS. 2A-3B illustrate the greater amount of volume shrink that occurs in the longer lengths of photoresist than the shorter lengths;

FIG. 4 illustrates a cross-sectional view of a partially completed semiconductor device at an initial stage of manufacture;

FIG. 5 illustrates the partially completed semiconductor device illustrated in FIG. 4 after using conventional processes to create a number of openings in the layer of photoresist material;

FIG. 6 illustrates a cross-sectional view of the partially completed semiconductor device illustrated in FIG. 5 after undergoing a hardbake process;

FIG. 7 illustrates the partially completed semiconductor device illustrated in FIG. 6 after a conventional implantation step;

FIG. 8 illustrates one embodiment of a semiconductor device constructed according to the method in FIGS. 4-7; and

FIG. 9 illustrates a cross-sectional view of an integrated circuit that might be manufactured according to the principles of the present invention.

### DETAILED DESCRIPTION

The present invention addresses the need for accurately and consistently attaining the low threshold voltages (Vₜ) required by today's semiconductor devices. As discussed in the detailed description above, the threshold voltage (Vₜ) attainable for a particular semiconductor device is at least partially dependent on the sidewall angle of the photoresist used to form the channel regions for that device. Up until the present invention, however, it was not known why the sidewall angles had an effect on the threshold voltage (Vₜ) As explained in more detail below, it has been found that the sidewall angle is important because it affects the resulting length of source implant under the gate.

Thus, the present invention addresses the previously unrecognized understanding of why the sidewall angles of the photoresist used to form the channel region have an effect on the threshold voltage (Vₜ). It has currently been discovered that the sloped sidewalls of the photoresist permit a portion of the dopant used to form the implanted region to partially penetrate into a part of a substrate that would otherwise not be accessible to the dopant if the photoresist sidewalls were substantially vertical. For example, the high implant energies currently used to implant the dopant into the substrate are thought to be high enough to drive a portion of the dopant through the thinned region of the photoresist material caused by the non-vertical sidewall. The photoresist sidewall angles, therefore, have an effect on the length of the implanted region, which in turn affects the threshold voltage (Vₜ).

It has also been found that the photoresist sidewall angles are sensitive to a number of process parameters including soft bake, focus and exposure, post-exposure bake, hardbake, developer temperature, developer concentration, and delay times between such single processing steps. Particularly, it has been discovered that the sidewall angles of longer lengths of photoresist are affected by the aforementioned process parameters substantially more than shorter lengths of photoresist. It is thought that a greater amount of solvent is driven from the longer lengths of photoresist than the shorter lengths of photoresist during the hardbake process, thus causing a volume of the longer lengths to shrink more than a volume of the shorter lengths.

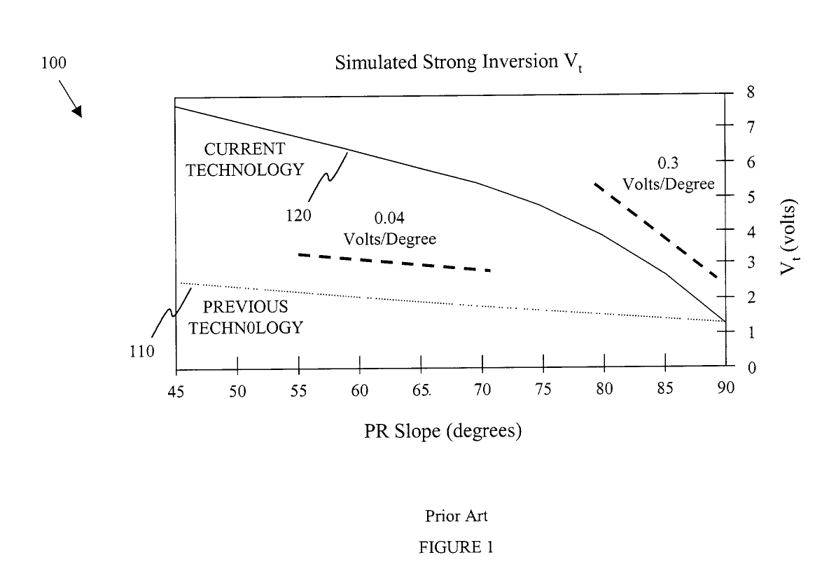

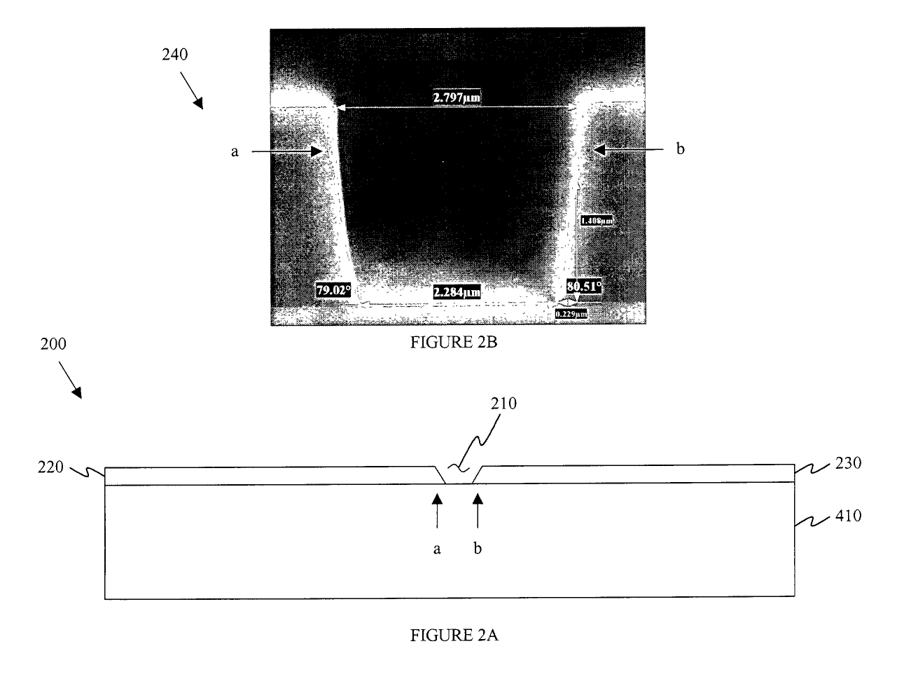

The greater amount of volume shrinkage in the longer lengths of photoresist, as compared to the shorter lengths, is illustrated in FIGS. 2A thru 3B. Turning to FIG. 2A, illustrated is a 1-finger example 200 wherein only a single opening 210 is formed between two longer lengths of photoresist 220, 230. A “finger” is an opening in a photoresist mask through which the photoresist is exposed. Subsequent processes leave an opening in the exposed portion of the photoresist in the case of a positive photoresist. As illustrated, both of the sidewalls a, b, are affected by the volume shrinkage of the longer lengths of photoresist 220, 230 after a hardbake. Accordingly, the sidewalls a, b, have sidewall angles substantially less than 90 degrees.

Turning briefly to FIG. 2B, illustrated is a micrograph 240 of the opening 210 having the sidewalls a, b. As illustrated in FIG. 2B, the sidewalls a, b, have sidewall angles of about 79.02° and about 80.51, respectively. As was indicated in Prior Art FIG. 1, such sidewall angles are generally not sufficient to achieve the low threshold voltages (Vₜ) required for today's semiconductor devices. Low threshold voltages are difficult to obtain under such circumstances due to the fact that the high implant energies can drive the dopants thru the thinner regions of the photoresist near the bottom of the opening, which results in the implant region length being longer than desired.

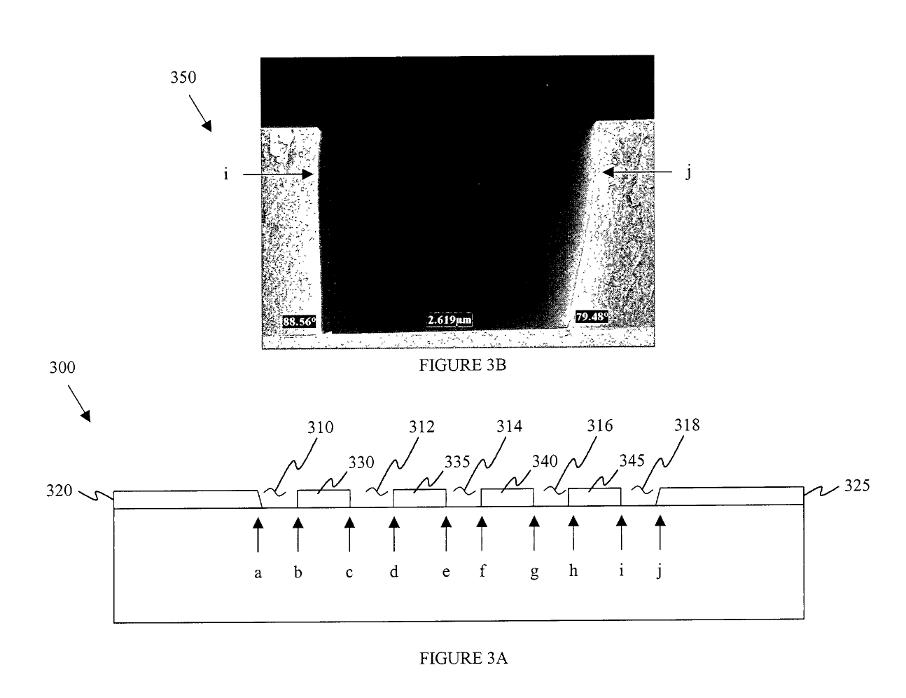

Turning now to FIG. 3A, illustrated is a 5-finger example 300, wherein five individual openings 310, 312, 314, 316, 318, are formed between two longer lengths of photoresist 320, 325 and four shorter lengths of photoresist 330, 335, 340, 345. Uniquely, only sidewalls a and j, which represent the sidewalls adjacent the two longer lengths of photoresist 320, 325, are substantially affected by the volume shrinkage. Accordingly, wherein sidewalls a and j have sidewall angles substantially less than 90 degrees, sidewalls b-i, which represent those sidewalls adjacent the shorter lengths of photoresist 330, 335, 340, 345, have sidewall angles close to about 90°.

Turning briefly to FIG. 3B, illustrated is a micrograph 350 of the opening 318 having the sidewalls i and j. As is illustrated in FIG. 3B, sidewall i defined by the shorter length of photoresist 345 has a sidewall angle of about 88.56°, and sidewall j defined by the longer length of photoresist 325 has a sidewall angle of about 79.48°. Accordingly, sidewall i appears to achieve a sidewall angle sufficient to attain the low threshold voltages (Vₜ) required for today's semiconductor devices, but in direct contrast, sidewall j clearly does not. It should be noted once again that the sidewall i is more perpendicular than sidewall j because the photoresist constituting sidewall i is significantly shorter than the photoresist constituting sidewall j.

Taking into account that discussed above, the present invention provides a method for manufacturing a semiconductor device that includes incorporating dummy openings into longer lengths of photoresist, wherein the dummy openings are positioned proximate active device openings and thereby reduce shrinkage in the photoresist that defines various implanted regions (e.g., channel regions). Accordingly, the dummy openings help inhibit nonuniform distortion of sidewall angles of the active device openings.

The following table illustrates the advantages provided by the present invention over those associated with conventional processes.

TABLE I

| | Electra pass-1 | Electra pass-2 |
|---|---|---|
| | w/o dummy body | with dummy body |
| LBC5 | mean threshold | mean threshold |
| scribeline data | voltage | voltage |
| 1-finger 40 V low-side LDMOS | 1.540 volts | 1.436 volts |
| 3-finger 40 V low-side LDMOS | 1.229 volts | 1.378 volts |
| threshold difference | 0.311 volts | 0.058 volts |

As can be seen from the foregoing TABLE I, the use of the present invention helps achieve consistent threshold voltage (Vₜ) values. For example, where the conventional method provides threshold voltage (Vₜ) values that vary across a single wafer by as much as about 0.311 volts, the use of the present invention provides threshold voltage (Vₜ) values that only vary by about 0.058 volts across the wafer. The smaller range provided by the use of the present invention, as those skilled in the art are well aware, is quite beneficial.

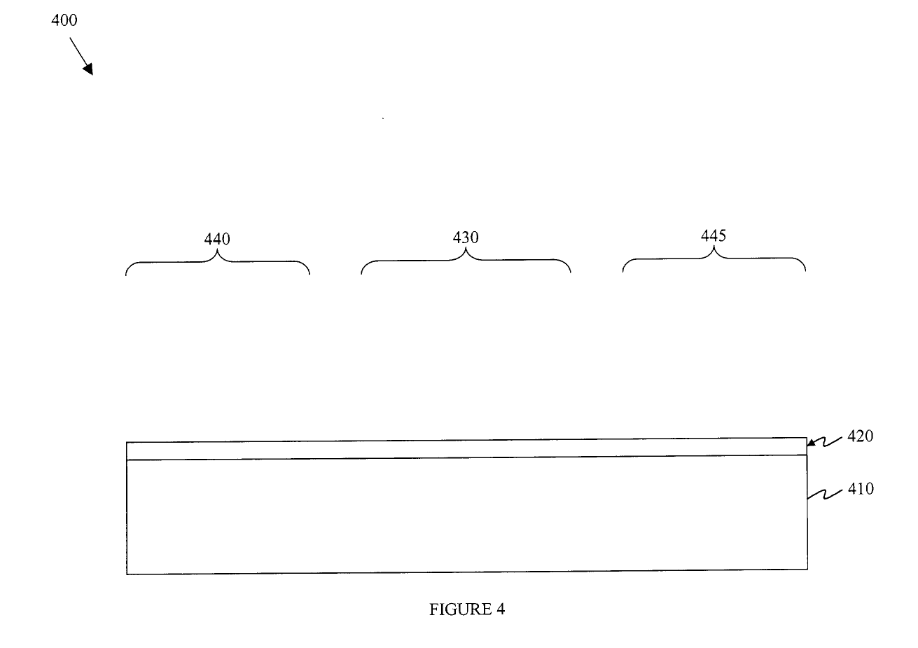

Turning to FIGS. 4-7, illustrated are cross-sectional views of detailed manufacturing steps instructing how one might, in an advantageous embodiment, manufacture a semiconductor device in accordance with the method set forth by the principles of the present invention. FIG. 4 illustrates a cross-sectional view of a partially completed semiconductor device 400 at an initial stage of manufacture. The partially completed semiconductor device 400 illustrated in FIG. 4 includes a substrate 410. The substrate 410 may, in an exemplary embodiment, be any layer located in the partially completed semiconductor device 400, including a wafer itself or a layer located above the wafer (e.g., an epitaxial layer). In the embodiment illustrated in FIG. 4, the substrate 410 is a P-type epitaxial layer; however, one skilled in the art understands that the substrate 410 could be an N-type epitaxial layer without departing from the scope of the present invention.

The embodiment of the partially completed semiconductor device 400 illustrated in FIG. 4, includes two different types of device regions. For example, the partially completed semiconductor device 400 includes an active device region 430 and two non-active device regions 440, 445. While only three device regions 430, 440, 445 have been shown in FIG. 4, those skilled in the art understand that any number of device regions could be formed in the substrate 410. However, for ease of discussion only three regions are illustrated and described.

In accordance with the present invention, an active device region is one in which a gate and its associated source and drain regions is to be formed. Typically, once fabricated the active devices are separated and isolated by field oxide regions. In contrast, non-active device regions are those regions in which the active transistor gates are not located, and may typically include regions in which device contacts may be formed.

In the embodiment shown in FIG. 4, the two non-active device regions 440, 445 happen to be substrate contact regions. As the two non-active regions 440, 445, of the embodiment depicted in FIG. 4 are relegated to the rather simple task of biasing the substrate 410, any incidental processing steps that might occur thereto (which will be discussed further below) do not have a substantial effect thereon.

Formed over the substrate 410 in the particular embodiment depicted in FIG. 4 is a layer of photoresist material 420. The layer of photoresist material 420, as shown, may be blanked deposited over both the active device region 430 and the non-active device regions 440, 445. As the deposition of the photoresist material 420 is conventional, further manufacturing details will be omitted.

The layer of photoresist material 420 may comprise a variety of materials and thicknesses while staying within the scope of the present invention. In one advantageous embodiment of the present invention the layer of photoresist material 420 comprises PFI-37, which may be easily obtained from Sumitomo Chemicals in Osaka Japan. Alternatively, the layer of photoresist material 420 may comprise SPR660, which may be easily obtained from Shipley Corporation in Newton, Mass. Additionally, the layer of photoresist material 420 may have a thickness of less than about 5 μm, and preferably a thickness ranging from about 1 μm to about 4.5 μm. It should be noted, however, that a variety of photoresist materials and thicknesses are well within the scope of the present invention.

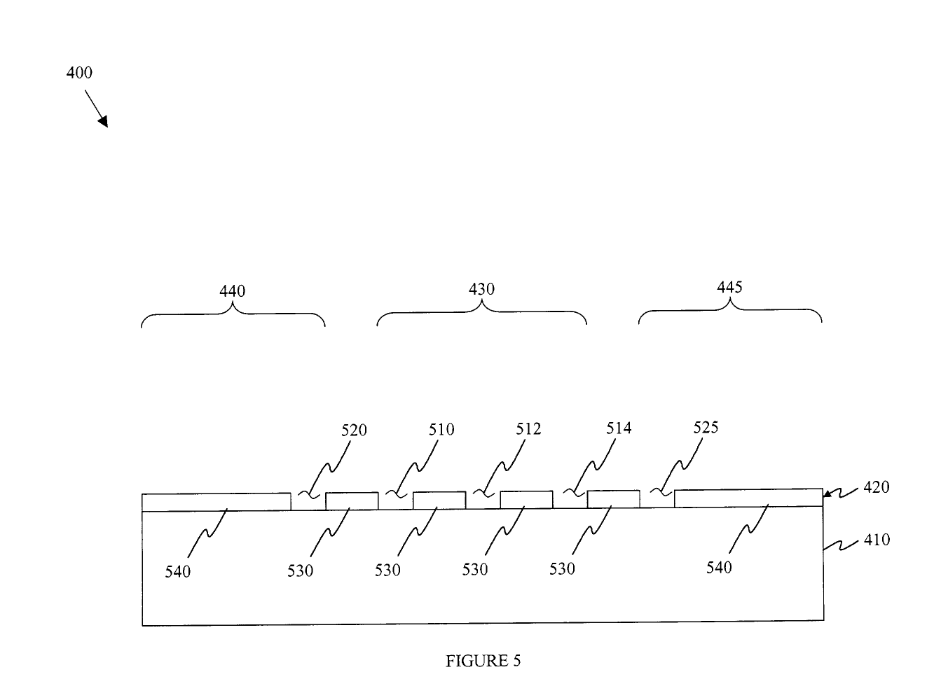

Turning now to FIG. 5, illustrated is the partially completed semiconductor device 400 illustrated in FIG. 4 after using conventional processes to create a number of openings in the layer of photoresist material 420. As shown, active device openings 510, 512, 514 have been formed in the active device region 430, and dummy openings 520, 525, have been formed in the non-active device regions 440, 445, respectively. What the active device openings 510, 512, 514 and the dummy openings 520, 525 accomplish is dividing the layer of photoresist material 420 shown in FIG. 4 up into four shorter lengths of photoresist 530 and two longer lengths of photoresist 540.

As illustrated, the dummy openings 520, 525 have been formed entirely through the layer of photoresist material 420. As is further illustrated, the dummy openings 520, 525 are located proximate the active device openings 510 and 514. The term proximate as used herein means that the dummy openings 520, 525 are located close enough such that the desired effect in the sidewalls of the opening in the photoresist is achieved. For example, in one embodiments, the dummy openings 520, 525 are less than about 12 μm from at least one adjacent active device opening. In another embodiment, the dummy openings 520, 525 may be positioned from about 9 μm to about 11 μm from the nearest active device opening.

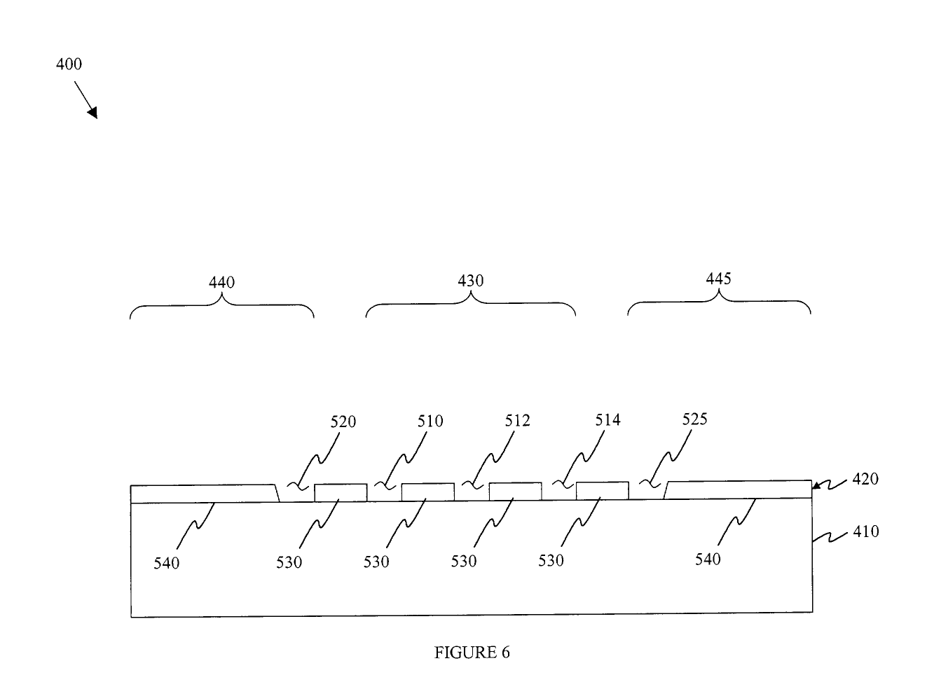

Turning now to FIG. 6, illustrated is a cross-sectional view of the partially completed semiconductor device 400 illustrated in FIG. 5 after undergoing a hardbake process. Note the unique collection of sidewall angles that results. Especially note how the dummy openings 520, 525 located proximate the active device openings 510 and 514 have reduced the shrinkage of the four shorter lengths of photoresist 530. In the illustrative embodiment shown in FIG. 6 only the sidewalls of the longer lengths of photoresist 540 have unacceptable sidewall angles. Further, the sidewalls of the shorter lengths of photoresist 530 deviate from one another by about 5 degrees or less. Optimally, the sidewalls of the shorter lengths of photoresist 530 deviate from one another by about 2 degrees or less.

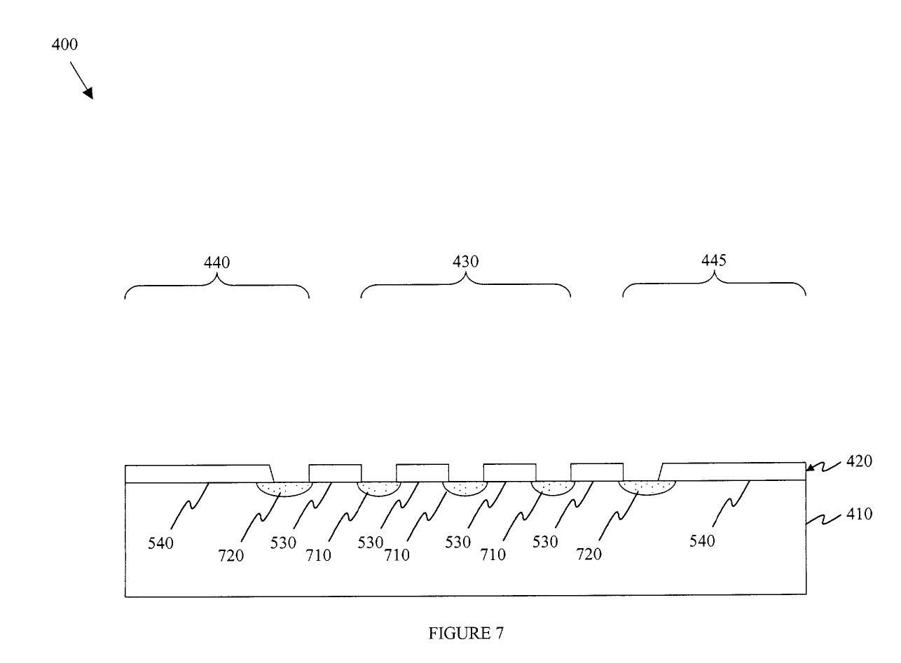

Turning briefly to FIG. 7, illustrated is the partially completed semiconductor device 400 illustrated in FIG. 6 after a conventional implantation step. As is illustrated, the implantation step forms implanted regions through the various openings 510, 512, 514, 520, 525 in the layer of photoresist material 420. The implanted regions, which in the present embodiment consist of active device implant regions 710 and dummy implant regions 720, are located in the surface of the substrate 410. As the active device implant regions 710 and dummy implant regions 720 were formed in a single processing step, they should have substantially similar dopant profiles. While many different conventional techniques may be used to manufacture the active device implant regions 710 and dummy implant regions 720, one particular advantageous embodiment of the present invention includes forming the regions 710, 720, using an implant energy ranging from about 50 keV to about 1 MeV. As the implant energy is relatively high, many of the novel aspects of the present invention have particular significance.

Note how the dummy implant regions 720 appear to be wider than the active device implant regions 710. As recited above, this is thought to be a function of the sloped sidewall angels of the dummy openings 520, 525. Fortunately, the dummy openings 520, 525 help substantially prevent the active device implant regions 710 from having undesirable implant characteristics, such as exist in the dummy implant regions 720. After completing the active device implant regions 710 and dummy implant regions 720, the semiconductor device 400 would be completed using a number of conventional processing steps.

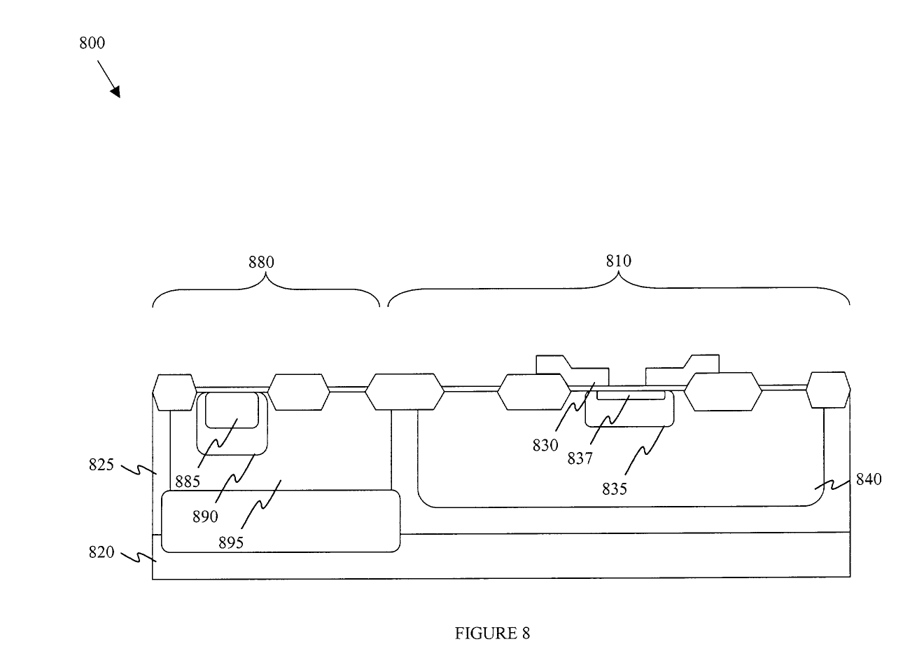

Turning now to FIG. 8, illustrated is one embodiment of a semiconductor device 800 constructed according to the method described above. The semiconductor device 800 illustrated in FIG. 8 happens to be an LDMOS device, however, those skilled in the art should understand that any semiconductor device 800 within the broad scope of the present invention could be used. For example, in an alternative embodiment the semiconductor device 800 could comprise a CMOS device, a BiCMOS device, a Bipolar device or another similar device. Semiconductor devices having channel regions are particularly useful as the semiconductor device 800. Even though many types of semiconductor devices could be used, for simplicity, the semiconductor device 800 will be discussed as an LDMOS. Accordingly, from this point forward the semiconductor device 800 will be referred to as the LDMOS device 800.

In the embodiment shown in FIG. 8, the LDMOS device 800 includes an active device region 810 and a non-active device region 880. While the non-active device region 880 shown in FIG. 8 is illustrated as a substrate contact region, those skilled in the art understand that various other non-active device regions 880 are within the scope of the present invention. For example, in one particular embodiment of the present invention, the non-active device region 880 is an unoccupied region of epitaxial silicon located proximate the active device region 810. While those skilled in the art do not generally waste semiconductor wafer real estate on such unoccupied regions, for purposes of the present invention a properly placed unoccupied region could be quite beneficial.

The advantageous embodiment shown in FIG. 8 has both the active device region 810 and non-active device region 880 located over a semiconductor wafer 820 and a substrate 825. As disclosed above, the substrate 825 may be any layer located in a semiconductor device, including a layer located at wafer level or any layer located thereover. In actuality, the substrate 825 could be the semiconductor wafer 820.

In the advantageous embodiment shown in FIG. 8, the active device region 810 includes a gate 830 located over an LDMOS well 835. The LDMOS well 835 generally includes a dopant such as boron (a P-type dopant) or phosphorous (an N-type dopant). In the particular embodiment shown, the LDMOS well 835 includes the P-type dopant. If, however, the LDMOS well 835 were doped with the N-type dopant, the dopant convention used throughout the remainder of this discussion would, of course, be reversed.

The LDMOS well 835, as shown, may be located within a deep well 840. The deep well 840, in an exemplary embodiment, is doped with a dopant opposite to the dopant used for the LDMOS well 835. Thus, if the LDMOS well 835 were doped with the P-type dopant, the deep well 840 would be doped with the N-type dopant, and vice-versa.

As illustrated, located within the LDMOS well 835 is a shallow doped region 837. In the particular embodiment shown, the shallow doped region 837 is an arsenic implant. As is well known, the LDMOS well 835 and shallow doped region 837 collectively form a channel region for the LDMOS device 800.

In the advantageous embodiment shown in FIG. 8, the non-active device region 880 includes a dummy LDMOS well 885. In the particular embodiment shown, the dummy LDMOS well 885 is located in a substrate contact region and proximate the LDMOS well 835. The dummy LDMOS well 885, in one embodiment, contains the same dopant as the LDMOS well 835. For example, in many cases the LDMOS well 835 and the dummy LDMOS well 885 are formed during a single processing step. In such instances, the LDMOS well 835 and the dummy LDMOS well 885 would have substantially similar dopant profiles.

As is further illustrated in FIG. 8, the dummy LDMOS well 885 may be located in a substrate contact shallow well 890. The substrate contact shallow well 890 generally contains the same type dopant as the dummy LDMOS well 885. Accordingly, in the current example, the substrate contact shallow well 890 contains the P-type dopant. Further, as illustrated, the substrate contact shallow well 890 may be located within a second deep well 895.

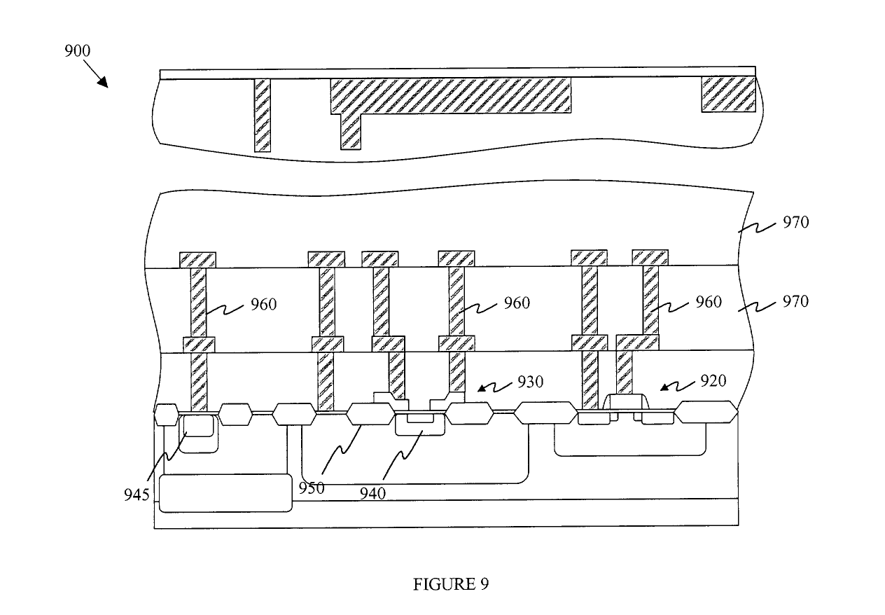

Turning now to FIG. 9, illustrated is a cross-sectional view of an integrated circuit 900 that might be manufactured according to the principles of the present invention. The integrated circuit 900 of FIG. 9 includes a CMOS device 920 and a semiconductor device 930 (similar to the semiconductor device 800 illustrated in FIG. 8), both of which are located over a substrate 910. The semiconductor device 930, as would be expected, includes both an LDMOS well 940, and a dummy LDMOS well 945 located proximate thereto. As shown, field oxide structures 950 may be located along the surface of the substrate 910, electrically isolating the various devices 920, 930 from one another. Also shown in FIG. 9 are interconnect structures 960 located in interlevel dielectric layers 970, wherein the interconnect structures 960 connect the CMOS device 920 and the semiconductor device 930 to other areas of the integrated circuit 900 creating an operative integrated circuit.

Although the present invention has been described in detail, those skilled in the art should understand that they can make various changes, substitutions and alterations herein without departing from the spirit and scope of the invention in its broadest form.

What is claimed is:

1. A method of manufacturing a semiconductor device, comprising:
depositing a layer of photoresist material over a substrate;
creating an active device opening through said photoresist material, said active device opening having sidewall angles associated therewith; and
forming a dummy opening through said photoresist material wherein said dummy opening is located proximate said active device opening to reduce a shrinkage of said photoresist between said dummy opening and said active device opening and thereby inhibit nonuniform distortion of said sidewall angles.

2. The method as recited in claim 1 wherein said creating and said forming include creating and forming in a single step.

3. The method as recited in claim 1 wherein forming includes forming a dummy opening within less than about 12 μm from said active device opening.

4. The method as recited in claim 1 further including simultaneously implanting a well and a dummy well through said active device opening and said dummy opening, respectively, wherein said well and said dummy well have substantially similar dopant profiles.

5. The method as recited in claim 4 wherein implanting a well includes implanting a P-type or an N-type dopant into said substrate creating a channel region for an LDMOS device.

6. The method as recited in claim 1 wherein said active device opening is a first active device opening, and said method further includes creating a first channel region through said first active device opening and said method further includes creating a second channel region through a second active device opening and adjacent said first channel region and forming a dummy opening includes forming first and second dummy openings proximate and on opposite sides of said first and second active device openings, respectively, wherein said first and second channel regions have substantially similar dopant profiles.

7. The method as recited in claim 1 wherein forming a dummy opening includes forming first and second dummy openings on first and second sides of said active device opening, respectively, wherein said first dummy opening inhibits nonuniform distortion of a first sidewall angle of said active device opening, and said second dummy opening inhibits nonuniform distortion of a second sidewall angle of said active device opening.

8. An LDMOS, comprising:
a gate located over an LDMOS well doped with a dopant, wherein said LDMOS well is located in a deep well doped with an opposite dopant; and
a dummy LDMOS well located in a non-active device region and proximate said LDMOS well, wherein said dummy LDMOS well is doped with said dopant.

9. The LDMOS device as recited in claim 8 wherein said LDMOS well and said dummy LDMOS well have substantially similar dopant profiles.

10. The LDMOS device as recited in claim 8 wherein said dummy LDMOS well is located less than about 12 μm from said LDMOS well.

11. The LDMOS device as recited in claim 10 wherein said dummy LDMOS well is located from about 9 μm to about 11 μm from said LDMOS well.

12. The LDMOS device as recited in claim 8 wherein said dummy LDMOS well is located within a substrate contact shallow well having a similar dopant.

13. The LDMOS device recited in claim 12 wherein said LDMOS well, said dummy LDMOS well and said substrate contact shallow well include a P-type dopant, and said deep well includes an N-type dopant.

14. The LDMOS device recited in claim 12 wherein said deep well is a first deep well, and said substrate contact shallow well is located within a second deep well.

15. A method for manufacturing an integrated circuit, comprising:
forming a semiconductor device over a substrate, including;
creating active device openings through a photoresist material, said active device openings having sidewall angles associated therewith;
forming dummy openings through said photoresist material wherein a dummy opening is located proximate and on at least one side of an active device opening, wherein said dummy openings are configured to reduce a shrinkage of said photoresist between said dummy openings and said active device openings, and thereby inhibiting nonuniform distortion of said sidewall angles; and
forming active devices between said dummy openings; and
interconnecting said active devices to form an operative integrated circuit.

16. The method as recited in claim 15 wherein forming active devices between said dummy openings includes implanting a P-type or N-type dopant into said substrate creating channel regions for LDMOS devices.

17. The method as recited in claim 16 further including forming a dummy LDMOS well in a non-active device region simultaneous with implanting a P-type or N-type dopant.

18. The method as recited in claim 16 wherein creating channel regions for LDMOS devices includes creating channel regions having substantially similar dopant profiles.

19. The method as recited in claim 15 wherein said sidewall angles of said active device openings deviate from one another by about 5 degrees or less.

20. The method as recited in claim 15 wherein said operative integrated circuit includes devices selected from a group consisting of:
LDMOS devices,
CMOS devices,
BiCMOS devices, and
Bipolar devices.
